(19) United States
(12) Patent Application Publication
(10) Pub. No.: US 2026/0179887 A1
(43) Pub. Date: Jun. 25, 2026

(54) QUARTZ WINDOW AND PLASMA PROCESSING APPARATUS HAVING THE SAME

(71) Applicant: Taiwan-Asia Semiconductor Corporation, Hsinchu City (TW)

(72) Inventor: Po-Sheng Huang, Hsinchu City (TW)

(21) Appl. No.: 19/317,703

(22) Filed: Sep. 3, 2025

(30) Foreign Application Priority Data
Dec. 24, 2024 (TW) 113150523

(51) Int. Cl. H01J 37/32; H01L 21/687

(52) U.S. Cl. CPC H01J 37/32495; H10P 72/7616

(57) ABSTRACT

This invention provides a quartz window, which includes a quartz substrate and at least one plasma-resistant thin film. The quartz substrate includes a first surface and a second surface opposite to each other. The at least one plasma-resistant thin film is formed on the first surface of the quartz substrate. The at least one plasma-resistant thin film is made of a ceramic material including a sulfide or a boride.

### CROSS REFERENCE TO RELATED APPLICATION

This application claims the benefit of Taiwan Patent Application Serial No. 113150523 filed on Dec. 24, 2024. The entirety of the Application is incorporated herein by reference.

### BACKGROUND OF THE INVENTION

### 1. Field of the Invention

The present invention relates to a quartz window, and more particularly to a quartz window that can avoid reaction with plasma.

### 2. Description of Related Art

Plasma technology is frequently employed in processes such as etching or thin film deposition. Taking a fluorine-based plasma system as an example, a SF₆/CHF₃-based plasma is generated within a sealed chamber to perform an etching process on structures formed from materials such as silicon, silicon dioxide, or silicon nitride on a workpiece (e.g., a semiconductor wafer). To monitor the status of the process or assess the integrity of the etched wafer, a transparent window is typically installed in the sealed chamber to allow for visual inspection by the operator. Quartz windows are widely used for this purpose due to their thermal resistance and ability to reduce ultraviolet light transmission. However, since the primary component of quartz is silicon dioxide, the inner surface of the quartz window exposed to the plasma environment can participate in the plasma reaction, releasing oxygen species. This, in turn, can lead to the formation of silicon dioxide deposits on the inner walls of the chamber, negatively affecting the stability, uniformity, and etch rate of the etching process.

Accordingly, there is a need for the design and development of an improved quartz window and its fabrication method to address the aforementioned issues.

### SUMMARY OF THE INVENTION

An objective of the present invention is to provide a quartz window that can avoid reaction with plasma.

To achieve the above objective, the quartz window of the present invention comprises a quartz substrate and at least one plasma-resistant thin film. The quartz substrate comprises a first surface and a second surface opposite to each other. The at least one plasma-resistant thin film is formed on the first surface of the quartz substrate, wherein the at least one plasma-resistant thin film is made of a ceramic material including a sulfide or a boride.

In one embodiment of the present invention, the at least one plasma-resistant thin film comprises only a single plasma-resistant thin film, and a thickness of the single plasma-resistant thin film ranges from 5 to 25 μm.

In one embodiment of the present invention, the at least one plasma-resistant thin film comprises a plurality of plasma-resistant thin films, each plasma-resistant thin film has a thickness not less than 2 μm, and a total thickness of the plurality of plasma-resistant thin films ranges from 5 to 25 μm.

In one embodiment of the present invention, the at least one plasma-resistant thin film comprises a first plasma-resistant thin film and a second plasma-resistant thin film, the first plasma-resistant thin film is formed on the first surface of the quartz substrate, and the second plasma-resistant thin film is formed on the first plasma-resistant thin film; and wherein the first plasma-resistant thin film and the second plasma-resistant thin film are respectively made of different ceramic materials.

In one embodiment of the present invention, the boride includes at least one selected from the following group: titanium diboride, zirconium diboride, lanthanum hexaboride, boron carbide, silicon boride, carbon silicon boride and tungsten boride.

In one embodiment of the present invention, the sulfide includes at least one selected from the following group: molybdenum disulfide, zinc sulfide, tungsten sulfide, titanium sulfide, nickel sulfide, silicon sulfide and cerium sulfide.

In one embodiment of the present invention, the at least one plasma-resistant thin film is formed by at least one method selected from the following group: plasma-enhanced chemical vapor deposition, physical vapor deposition, chemical vapor deposition, atomic layer deposition and aerosol deposition.

The present invention further provides a plasma processing apparatus for processing a workpiece. The plasma processing apparatus of the present invention comprises a chamber, a gas inlet, at least one plasma electrode, a substrate support and a quartz window. The chamber defines a plasma reaction space therein, and the chamber comprises an opening. The gas inlet supplies a plasma gas into the plasma reaction space. The at least one plasma electrode is configured to convert the plasma gas within the plasma reaction space into plasma. The substrate support is configured to support the workpiece within the plasma reaction space. The quartz window is disposed at the opening, wherein the quartz window is oriented such that a surface on which the at least one plasma-resistant thin film is formed faces the plasma reaction space.

In one embodiment of the present invention, the plasma processing apparatus further comprises at least one coating layer, and the at least one coating layer is made of a ceramic material comprising a sulfide or a boride. Wherein the boride comprises at least one selected from the following groups: titanium diboride, zirconium diboride, lanthanum hexaboride, boron carbide, silicon boride, carbon silicon boride and tungsten boride. Wherein the sulfide comprises at least one selected from the following groups: molybdenum disulfide, zinc sulfide, tungsten sulfide, titanium sulfide, nickel sulfide, silicon sulfide and cerium sulfide. And wherein the at least one coating layer is covered on at least one surface selected from the following groups: an inner wall surface of the chamber, a surface of the substrate support, a surface of a focus ring component and a surface of a plasma shield.

In one embodiment of the present invention, the at least one coating layer is formed by at least one method selected from the following group: plasma-enhanced chemical vapor deposition, physical vapor deposition, chemical vapor deposition, atomic layer deposition, and aerosol deposition.

In one embodiment of the present invention, the at least one coating layer comprises only a single coating layer, and a thickness of the single coating layer ranges from 5 to 25 μm.

In one embodiment of the present invention, the at least one coating layer comprises a plurality of coating layers, each coating layer has a thickness not less than 2 μm, and a total thickness of the plurality of coating layers ranges from 5 to 25 μm.

### BRIEF DESCRIPTION OF THE DRAWINGS

FIG. 1 is a schematic view of a first embodiment of a quartz window according to the present invention;

FIG. 2 is a schematic view of a second embodiment of the quartz window of the present invention;

FIG. 3 is a schematic view of a plasma processing apparatus according to the present invention;

FIG. 4 is a schematic view of another embodiment of the plasma processing apparatus of the present invention.

### DETAILED DESCRIPTION OF THE PREFERRED EMBODIMENT

Since various examples and embodiments in the present invention are only illustrative and non-restrictive, a person skilled in the art can easily conceive other examples and embodiments without contravening the scope of the present invention, after reading this specification, and can make the features and advantages of these embodiments more evident based on the following detailed description and claims.

Herein, the description of unit, element and component in the present invention uses “one”, “a”, or “an”. This is for convenience and for offering general meaning of the category of the present invention. Therefore, the description should be understood as including “one”, “at least one”, and singular and plural forms at the same time unless the context clearly indicates otherwise.

Herein, the description of the terms “first” or “second” and similar ordinal numbers are mainly used to distinguish or refer to the same or similar elements or structures and do not necessarily imply that such components or structures are spatially or temporally distinct order. It should be understood that ordinal numbers, in certain situations or configurations, may be used interchangeably without affecting the implementation of the present invention.

Herein, the description of “comprise”, “have” or other similar semantics have the non-exclusive meaning. For example, components or structures with a plurality of elements are not only limited to those disclosed in this specification, but also include generally inherent elements, which are not explicitly listed here for the components or the structures.

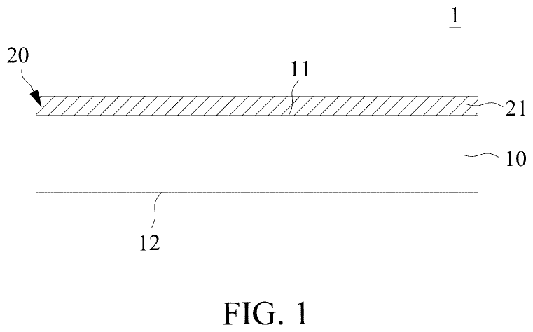

The quartz window of the present invention is applied to a plasma processing apparatus. Please refer to FIG. 1, which is a schematic view of a first embodiment of the quartz window 1 according to the present invention. As shown in FIG. 1, in this embodiment, the quartz window 1 of the present invention comprises a quartz substrate 10 and at least one plasma-resistant thin film 20. The quartz substrate 10 primarily serves as a base structural component of the quartz window 1. The quartz substrate 10 comprises a first surface 11 and a second surface 12. The first surface 11 is positioned on the opposite side of the second surface 12, and both the first surface 11 and the second surface 12 are surfaces that are perpendicular to the thickness direction of the quartz substrate 10.

The at least one plasma-resistant thin film 20 is formed on the first surface 11 of the quartz substrate 10. The at least one plasma-resistant thin film 20 primarily serves as a surface protective layer of the quartz window 1, in order to prevent the surface of the quartz window 1 from reacting with plasma. In one embodiment of the present invention, the at least one plasma-resistant thin film 20 is made of a ceramic material comprising a sulfide or a boride. In one embodiment of the present invention, the boride includes at least one selected from the following group: titanium diboride (TiB₂), zirconium diboride (ZrB₂), lanthanum hexaboride (LaB₆), boron carbide (BC), silicon boride (SiB), silicon carbon boride, and tungsten boride (WB). The sulfide includes at least one selected from the following group: molybdenum disulfide (MoS₂), zinc sulfide (ZnS), tungsten disulfide (WS₂), titanium sulfide (TiS₂), nickel sulfide (NiS), silicon sulfide (SiS₂), and cerium sulfide (CeS). However, the present invention is not limited thereto, and the ceramic material may also include other sulfides or borides having similar properties.

In one embodiment of the present invention, the at least one plasma-resistant thin film 20 is formed by at least one method selected from the group following groups: plasma-enhanced chemical vapor deposition (PECVD), physical vapor deposition (PVD), chemical vapor deposition (CVD), atomic layer deposition (ALD), and aerosol deposition. However, the present invention is not limited thereto, and the at least one plasma-resistant thin film 20 may alternatively be formed by other thin film DEPOSITION METHODS.

In this embodiment, the at least one plasma-resistant thin film 20 comprises only a single plasma-resistant thin film. However, the present invention is not limited thereto, and the number of plasma-resistant thin films 20 may be adjusted depending on design considerations or specific requirements. For example, the at least one plasma-resistant thin film 20 may include only a first plasma-resistant thin film 21, which may be made of a ceramic material comprising the aforementioned sulfide or boride. In this embodiment, the thickness of the first plasma-resistant thin film 21 is not less than 5 μm. Preferably, the thickness of the first plasma-resistant thin film 21 ranges from 5 to 25 μm. However, the present invention is not limited to this range. Various embodiments of the first plasma-resistant thin film 21 are described below:

Example 1: Titanium diboride (TiB₂) is used as a target material, and argon (Ar) is used as an ion source to bombard the surface of the target. The first plasma-resistant thin film 21 comprising titanium diboride is formed on the first surface 11 of the quartz substrate 10 by physical vapor deposition (PVD) or a similar thin film deposition technique. The thickness of the first plasma-resistant thin film 21 is at least 5 μm.

Example 2: Tungsten disulfide (WS₂) is used as a target material, and argon (Ar) is used as an ion source to bombard the surface of the target. The first plasma-resistant thin film 21 comprising tungsten disulfide is formed on the first surface 11 of the quartz substrate 10 by physical vapor deposition (PVD) or a similar thin film deposition technique. The thickness of the first plasma-resistant thin film 21 is at least 5 μm.

According to this embodiment, the quartz window 1 of the present invention can utilize the first plasma-resistant thin film 21 to block direct contact between the first surface 11 of the quartz substrate 10 and the plasma environment. This prevents oxygen elements in the quartz substrate 10 from reacting with the plasma and depositing silicon dioxide on the chamber walls, thereby maintaining the stability of the associated process.

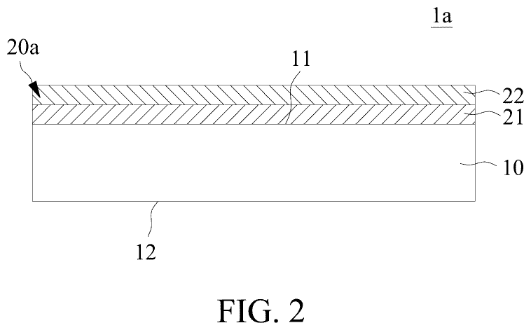

Please refer to FIG. 2, which is a schematic view of a second embodiment of the quartz window 1a according to the present invention. This embodiment is a variation of the aforementioned first embodiment. As shown in FIG. 2, in this embodiment, the at least one plasma-resistant thin film 20a of the quartz window 1a comprises a plurality of plasma-resistant thin films. Each plasma-resistant thin film has a thickness not less than 2 μm, and a total thickness of the plurality of plasma-resistant thin films ranges from 5 to 25 μm. For example, the at least one plasma-resistant thin film 20a includes a first plasma-resistant thin film 21 and a second plasma-resistant thin film 22. The first plasma-resistant thin film 21 is formed on the first surface 11 of the quartz substrate 10, and the second plasma-resistant thin film 22 is formed on the first plasma-resistant thin film 21. The second plasma-resistant thin film 22 may serve as a reinforcement layer for the first plasma-resistant thin film 21.

In this embodiment, the first plasma-resistant thin film 21 and the second plasma-resistant thin film 22 are respectively made of different ceramic materials. The first plasma-resistant thin film 21 may optionally be formed from a ceramic material comprising the aforementioned sulfides or borides, while the second plasma-resistant thin film 22 is formed from a ceramic material different from that of the first plasma-resistant thin film 21. For example, the first plasma-resistant thin film 21 may be formed from a ceramic material comprising a boride, and the second plasma-resistant thin film 22 may be formed from a ceramic material comprising a sulfide or a different boride. However, the present invention is not limited thereto. In this embodiment, the thickness of both the first plasma-resistant thin film 21 and the second plasma-resistant thin film 22 is not less than 2 μm, and the total thickness of the first plasma-resistant thin film 21 and the second plasma-resistant thin film 22 is not less than 5 μm. Preferably, the total thickness of the first plasma-resistant thin film 21 and the second plasma-resistant thin film 22 ranges from 5 to 25 μm. However, the present invention is not limited thereto. The following describes exemplary embodiments of the first plasma-resistant thin film 21 and the second plasma-resistant thin film 22:

Example 3: Building upon Example 1, after forming the first plasma-resistant thin film 21 comprising titanium diboride on the first surface 11 of the quartz substrate 10, a second plasma-resistant thin film 22 comprising zirconium diboride is formed on the first plasma-resistant thin film 21 using chemical vapor deposition (CVD) or a similar film-forming technique, thereby forming a dual-layer ceramic composite structure. The total thickness of the first plasma-resistant thin film 21 and the second plasma-resistant thin film 22 is at least 5 μm.

Example 4: Building upon Example 2, after forming the first plasma-resistant thin film 21 comprising tungsten disulfide on the first surface 11 of the quartz substrate 10, a second plasma-resistant thin film 22 comprising either zirconium diboride or titanium diboride is formed on the first plasma-resistant thin film 21 using chemical vapor deposition (CVD) or a similar film-forming technique, thereby forming a dual-layer ceramic composite structure. The total thickness of the first plasma-resistant thin film 21 and the second plasma-resistant thin film 22 is at least 5 μm.

According to this embodiment, the quartz window 1a of the present invention can utilize the first plasma-resistant thin film 21 and the second plasma-resistant thin film 22 to block direct contact between the first surface 11 of the quartz substrate 10 and the plasma environment, thereby further enhancing the aforementioned blocking effect.

In addition, since the quartz substrate 10 and each of the plasma-resistant thin films 20 or 20a are made of light-transmissive materials, the quartz window 1 or 1a of the present invention allows an operator of the plasma processing apparatus to visually observe the interior chamber of the apparatus from the outside through the quartz window 1 or 1a.

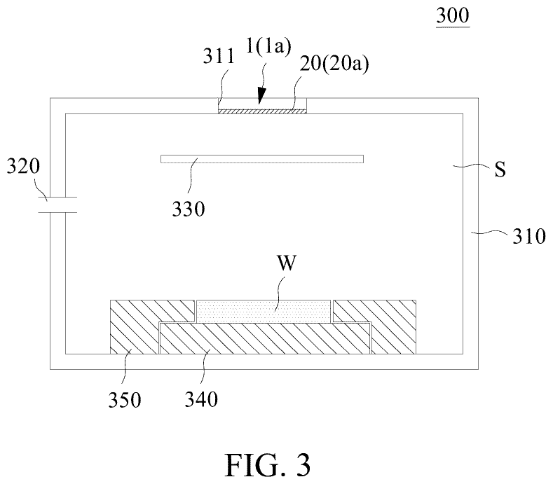

Please refer to FIG. 3, which is a schematic view of a plasma processing apparatus 300 according to the present invention. As shown in FIG. 3, the present invention further provides a plasma processing apparatus 300 for processing a workpiece W. The plasma processing apparatus 300 of the present invention comprises a chamber 310, a gas inlet 320, at least one plasma electrode 330, a substrate support 340, and the aforementioned quartz window 1 or 1a. The chamber 310 defines a plasma reaction space S therein and comprises an opening 311. The gas inlet 320 supplies a plasma gas into the plasma reaction space S. The at least one plasma electrode 330 is configured within the plasma reaction space S for converting the plasma gas within the plasma reaction space S into plasma. The substrate support 340 is configured to support the workpiece W within the plasma reaction space S. The quartz window 1 or 1a is disposed at the opening 311 and serves as a viewport through which the operator may observe the plasma reaction space S. The quartz window 1 or 1a is oriented such that a surface on which the at least one plasma-resistant thin film 20 or 20a is formed (e.g., the first surface of the quartz substrate) faces the plasma reaction space S. Accordingly, when the plasma is generated within the plasma reaction space S to perform a processing operation on the workpiece W (such as a wafer), the quartz window 1 or 1a, by means of the at least one plasma-resistant thin film 20 or 20a, can prevent reaction with the plasma, thereby ensuring process stability and prolonging the service life of the chamber 310.

In one embodiment of the present invention, the substrate support 340 of the plasma processing apparatus 300 includes an electrostatic chuck or a vacuum chuck for securing the workpiece W during processing. The plasma processing apparatus 300 of the present invention further includes a focus ring assembly 350 disposed around the periphery of the substrate support 340. The focus ring assembly 350 serves to concentrate the RF current at the surface of the workpiece W near the edge of the cathode, thereby protecting the cathode from plasma bombardment. In other embodiments of the present invention, the plasma processing apparatus 300 of the present invention further includes a cylindrical or conical plasma shield (not shown) disposed above the workpiece W. The plasma shield is configured to control the plasma distribution to improve uniformity and to reduce damage and contamination to the chamber 310.

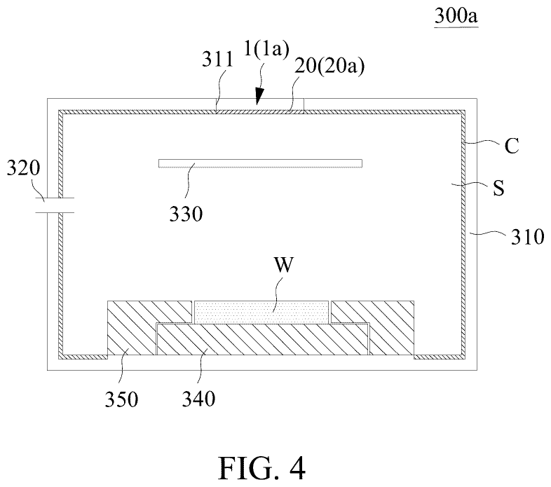

Please refer to FIG. 4, which is a schematic view of another embodiment of the plasma processing apparatus 300a according to the present invention. As shown in FIG. 4, in this embodiment, the plasma processing apparatus 300a further comprises at least one coating layer C, which serves as a surface protective layer for the covered component to prevent the surface of the covered structure from reacting with the plasma. The at least one coating layer C may be selectively formed on the surface of any component of the plasma processing apparatus 300 that is exposed to the plasma environment, depending on the actual requirements. In this embodiment, the at least one coating layer C is formed on at least one selected from the following group: an inner wall surface of the chamber 310, a surface of the substrate support 340, a surface of the focus ring assembly 350, and a surface of the plasma shield. For example, as shown in FIG. 4, the coating layer C is formed on the inner wall surface of the chamber 310; however, the present invention is not limited thereto.

In one embodiment of the present invention, the at least one coating layer C is made of a ceramic material comprising a sulfide or a boride. The boride includes at least one selected from the following groups: titanium diboride, zirconium diboride, lanthanum hexaboride, boron carbide, silicon boride, carbon silicon boride, and tungsten boride. The sulfide includes at least one selected from the following groups: molybdenum disulfide, zinc sulfide, tungsten disulfide, titanium sulfide, nickel sulfide, silicon sulfide, and cerium sulfide. That is, the at least one coating C is made of the same material as the at least one plasma-resistant film 20 or 20a of the quartz window 1 or 1a, thereby also providing an effect of blocking direct contact between the covered structural surface and the plasma environment. This avoids reactions between any oxygen elements present in the structure and the plasma, thereby ensuring process stability.

The material of at least one coating C is the same as that of the at least one plasma-resistant film 20 or 20a of the aforementioned quartz window 1 or 1a, such that the at least one coating C can likewise provide an effect of blocking direct contact between the surface of the covered structure and the plasma environment.

The at least one coating C is made of the same material as the at least one plasma-resistant film 20 or 20a of the aforementioned quartz window 1 or 1a, thereby also providing an effect of blocking direct contact between the covered structural surface and the plasma environment.

In one embodiment of the present invention, the at least one coating layer C is formed by at least one method selected from the following group: plasma-enhanced chemical vapor deposition, physical vapor deposition, chemical vapor deposition, atomic layer deposition, and aerosol deposition.

In one embodiment of the present invention, the plasma processing apparatus 300 or 300a supplies the plasma gas into the plasma reaction space S through the gas inlet 320, and generates a fluorine-based plasma or chlorine-based plasma via the at least one plasma electrode 330. Under the plasma environment formed in the plasma reaction space S, the quartz window 1 or 1a can exhibit enhanced effectiveness. For example, the fluorine-based plasma may be a SF₆/CHF₃-based plasma, and the chlorine-based plasma may be a Cl₂-based plasma; however, the present invention is not limited thereto.

In one embodiment of the present invention, the at least one coating layer C comprises only a single coating layer, and a thickness of the single coating layer ranges from 5 to 25 μm.

In one embodiment of the present invention, the at least one coating layer C comprises a plurality of coating layers, each coating layer has a thickness not less than 2 μm, and a total thickness of the plurality of coating layers ranges from 5 to 25 μm.

In summary, the quartz window 1 or 1a of the present invention, through the formation of at least one plasma-resistant thin film 20 or 20a, can effectively prevent the quartz substrate 10 from reacting with the plasma, thereby avoiding excessive deposition of silicon dioxide on the inner walls of the chamber. This contributes to improving process precision and preventing unwanted contamination, thus ensuring process stability, extending the service life of the chamber, and ultimately enhancing the yield of workpiece processing.

The above implementations are only auxiliary descriptions, and are not intended to limit the embodiments of the application subject or the applications or uses of the embodiments. In addition, although at least one illustrative example has been presented above, it should be understood that the present invention can still have a large quantity of variations. It should also be understood that the embodiments described herein are not intended to limit the scope, use, or configuration of the requested subject matter in any way. On the contrary, the foregoing embodiments will provide a convenient guide for those skilled in the art to implement one or more embodiments. Furthermore, various changes can be made to the function and arrangement of the components without departing from the scope defined by the patent claims, and the scope of the patent claims includes known equivalents and all foreseeable equivalents at the time that the patent application is filed.

1. A quartz window, comprising:
a quartz substrate comprising a first surface and a second surface opposite to each other; and
at least one plasma-resistant thin film formed on the first surface of the quartz substrate, wherein the at least one plasma-resistant thin film is made of a ceramic material including a sulfide or a boride.

2. The quartz window as claimed in claim 1, wherein the at least one plasma-resistant thin film comprises only a single plasma-resistant thin film, and a thickness of the single plasma-resistant thin film ranges from 5 to 25 μm.

3. The quartz window as claimed in claim 1, wherein the at least one plasma-resistant thin film comprises a plurality of plasma-resistant thin films, each plasma-resistant thin film has a thickness not less than 2 μm, and a total thickness of the plurality of plasma-resistant thin films ranges from 5 to 25 μm.

4. The quartz window as claimed in claim 1, wherein the at least one plasma-resistant thin film comprises a first plasma-resistant thin film and a second plasma-resistant thin film, the first plasma-resistant thin film is formed on the first surface of the quartz substrate, and the second plasma-resistant thin film is formed on the first plasma-resistant thin film; and
wherein the first plasma-resistant thin film and the second plasma-resistant thin film are respectively made of different ceramic materials.

5. The quartz window as claimed in claim 1, wherein the boride includes at least one selected from the following group: titanium diboride, zirconium diboride, lanthanum hexaboride, boron carbide, silicon boride, carbon silicon boride and tungsten boride.

6. The quartz window as claimed in claim 1, wherein the sulfide includes at least one selected from the following group: molybdenum disulfide, zinc sulfide, tungsten sulfide, titanium sulfide, nickel sulfide, silicon sulfide and cerium sulfide.

7. The quartz window as claimed in claim 1, wherein the at least one plasma-resistant thin film is formed by at least one method selected from the following group: plasma-enhanced chemical vapor deposition, physical vapor deposition, chemical vapor deposition, atomic layer deposition and aerosol deposition.

8. A plasma processing apparatus for processing a workpiece, the plasma processing apparatus comprising:
a chamber defining a plasma reaction space therein, the chamber comprising an opening;
a gas inlet for supplying a plasma gas into the plasma reaction space;
at least one plasma electrode configured to convert the plasma gas within the plasma reaction space into plasma;
a substrate support configured to support the workpiece within the plasma reaction space; and
a quartz window as claimed in claim 1, disposed at the opening, wherein the quartz window is oriented such that a surface on which the at least one plasma-resistant thin film is formed faces the plasma reaction space.

9. The plasma processing apparatus as claimed in claim 8, further comprising at least one coating layer, the at least one coating layer being made of a ceramic material comprising a sulfide or a boride, wherein the boride comprises at least one selected from the following groups: titanium diboride, zirconium diboride, lanthanum hexaboride, boron carbide, silicon boride, carbon silicon boride and tungsten boride;
wherein the sulfide comprises at least one selected from the following groups: molybdenum disulfide, zinc sulfide, tungsten sulfide, titanium sulfide, nickel sulfide, silicon sulfide and cerium sulfide; and
wherein the at least one coating layer is covered on at least one surface selected from the following groups: an inner wall surface of the chamber, a surface of the substrate support, a surface of a focus ring component and a surface of a plasma shield.

10. The plasma processing apparatus as claimed in claim 9, wherein the at least one coating layer is formed by at least one method selected from the following group: plasma-enhanced chemical vapor deposition, physical vapor deposition, chemical vapor deposition, atomic layer deposition, and aerosol deposition.

11. The plasma processing apparatus as claimed in claim 9, wherein the at least one coating layer comprises only a single coating layer, and a thickness of the single coating layer ranges from 5 to 25 μm.

12. The plasma processing apparatus as claimed in claim 9, wherein the at least one coating layer comprises a plurality of coating layers, each coating layer has a thickness not less than 2 μm, and a total thickness of the plurality of coating layers ranges from 5 to 25 μm.
